(19) United States
(12) Patent Application Publication
(10) Pub. No.: US 2013/0269615 A1
(43) Pub. Date: Oct. 17, 2013

(54) VERTICAL WAFER BOAT

(71) Applicant: Steven R. A. Van Aerde, Almere (NL)

(72) Inventor: Steven R. A. Van Aerde, Almere (NL)

(73) Assignee: ASM IP Holding B.V., Almere (NL)

(21) Appl. No.: 13/447,771

(22) Filed: Apr. 16, 2012

(51) Int. Cl. B65D 85/00; C23C 16/458

(52) U.S. Cl. 118/730; 118/728; 206/710

(57) ABSTRACT

A wafer boat for holding a plurality of semiconductor wafers in a spaced apart relationship during processing, comprising at least one support member defining a plurality of sets of at least two vertically spaced apart wafer holding provisions, each of which wafer holding provisions is configured to independently hold a wafer in a substantially horizontal orientation, and wherein said sets are arranged such that the wafer boat is configured to accommodate a plurality of juxtaposed stacks of substantially horizontally oriented, vertically spaced apart wafers.

### FIELD OF THE INVENTION

The present invention relates to a vertical wafer boat for holding a plurality of semiconductor wafers in a spaced apart relationship during processing in a vertical batch furnace.

### BACKGROUND

Vertical batch furnaces are well known in the semiconductor fabrication industry and used to subject wafers, one batch at a time, to a variety of thermal treatments, such as oxidation, annealing, low pressure chemical vapor deposition (LPCVD), and atomic layer deposition (ALD). A vertical furnace includes at least one reactor in the form of a vertical, typically cylindrical reactor tube in which a wafer boat, holding a batch of wafers in a vertically spaced apart relationship, is receivable. The wafer boat and the reactor tube are tailored to the dimensions of the wafers, such that the reactor tube can be filled efficiently.

### SUMMARY OF THE INVENTION

Wafers are currently available in various standard diameters of 100 mm, 125 mm, 150 mm, 200 mm, and 300 mm. Over the past years, however, wafer sizes have gradually increased to improve throughput and reduce manufacturing costs, such that the range of sizes is expanding. The next standard wafer diameter is projected to be 450 mm.

To process wafers of a certain diameter in a vertical furnace, the furnace's reactor tube must have an inner diameter that exceeds the wafer diameter, or a vertical wafer stack will not fit inside. Conversely, furnaces having a reactor tube equipped to handle wafers of a certain diameter are generally also suited to handle wafers of an arbitrary smaller diameter. And even though the average wafer size is trending upwards, relatively small wafers, e.g. 150 mm wafers, are still in use for particular applications, e.g. LED's, and high power and RF circuits. Yet stacking these relatively small wafers in a conventional wafer boat geared towards their dimensions, and inserting the boat into the oversized reactor tube of a furnace configured to handle wafers of a significantly larger maximum or target diameter is inefficient and wasteful in terms of reactor capacity.

It is an object of the present invention to overcome this problem, and to enable a vertical furnace to efficiently process wafers of a relatively small size compared to its target wafer size, thereby optimizing reactor utilization and throughput.

To this end, a first aspect of the present invention is directed to a wafer boat for holding a plurality of semiconductor wafers in a spaced apart relationship during processing. The wafer boat may include at least one support member defining a plurality of sets of at least two vertically spaced apart wafer holding provisions. Each wafer holding provision may be configured to independently hold (i.e. without assistance from other wafer holding provisions) a wafer in a substantially horizontal orientation. The sets of wafer holding provisions may be arranged such that the wafer boat, and specifically the at least one support member thereof, is configured to accommodate a plurality of juxtaposed stacks of substantially horizontally oriented, vertically spaced apart wafers.

Where conventional vertical wafer boats are typically configured to hold one stack of mutually vertically spaced apart wafers, the presently disclosed wafer boat may be configured to accommodate a plurality of juxtaposed stacks of mutually vertically spaced apart wafers. The wafer boat may be used with any vertical furnace reactor defining a wafer boat reception space with a footprint or (vertically uniform) cross-sectional area that can accommodate multiple non-overlapping smaller wafers within its boundary. A vertical furnace for processing 300 mm wafers, for example, may include a generally cylindrical reactor tube that defines an inner cylindrical wafer boat reception space having a diameter of approximately 340 mm; the footprint of the reactor's wafer boat reception space may thus accommodate three non-overlapping 150 mm circular wafers. Accordingly, a wafer boat according to the present invention configured for use with said 300 mm furnace may accommodate three juxtaposed, parallel straight stacks of 150 mm wafers, instead of just one straight stack of a same height. It will therefore be appreciated that the wafer boat according to the present invention enables a significant increase in wafer throughput for wafers having sizes smaller than the target size of the employed reactor.

In a preferred embodiment, the wafer boat may include a first, preferably plate-shaped end member at a lower extremity of the wafer boat and a second preferably plate-shaped end member at an upper extremity of the wafer boat, while its at least one support member may include a plurality of rod-shaped support members, each interconnecting said end members and defining a plurality of vertically spaced apart wafer engagement provisions, e.g. recesses. Each set of wafer holding provisions may be defined by a set of at least two rod-shaped support members, and each individual holding provision of a certain set of wafer holding provisions may be defined by at least two wafer engagement provisions defined by the rod-shaped support members defining the respective set of wafer holding provisions.

Such an embodiment of the wafer boat, featuring a plurality of rod-shaped support members extending between two end members, may be manufactured at minimal material costs. In addition, the open structure of the wafer boat facilitates the flow of process gas therethrough during operation, and thus optimizes exposure of the wafers to the process gas.

A second aspect of the present invention is directed to a semiconductor processing apparatus, in particular a vertical furnace, comprising a wafer boat according to the first aspect of the present invention.

In a preferred embodiment, the semiconductor processing apparatus may comprise a reactor tube; a pedestal, supporting the wafer boat, and configured to be at least partly insertable into the reactor tube; and a multi-link wafer handling robot configured to load and unload wafers into and from the wafer holding provisions of each of the sets of wafer holding provisions of the wafer boat.

These and other features and advantages of the invention will be more fully understood from the following detailed description of certain embodiments of the invention, taken together with the accompanying drawings, which are meant to illustrate and not to limit the invention.

### BRIEF DESCRIPTION OF THE DRAWINGS

FIG. 1 shows a schematic perspective view of a first exemplary embodiment of a wafer boat according to the present invention;

FIG. 2 shows a schematic cross-sectional top view of the first exemplary embodiment of the wafer boat shown in FIG. 1 (left), and a perspective view of a wafer handling robot with a three-link articulated arm having an end-effector that is fixedly connected at an extremity thereof (right);

FIG. 3 shows a schematic cross-sectional top view of a second exemplary embodiment of a wafer boat according to the present invention (left), and a perspective view of a wafer handling robot with a three-link articulated arm having an end-effector that is movably connected at an extremity thereof (right);

FIG. 4 shows a schematic cross-sectional top view of a third exemplary embodiment of a wafer boat according to the present invention; and

FIG. 5 shows a schematic plan view of an exemplary semiconductor processing apparatus fitted with the first exemplary embodiment of the wafer boat shown in FIGS. 1 and 2.

### DETAILED DESCRIPTION

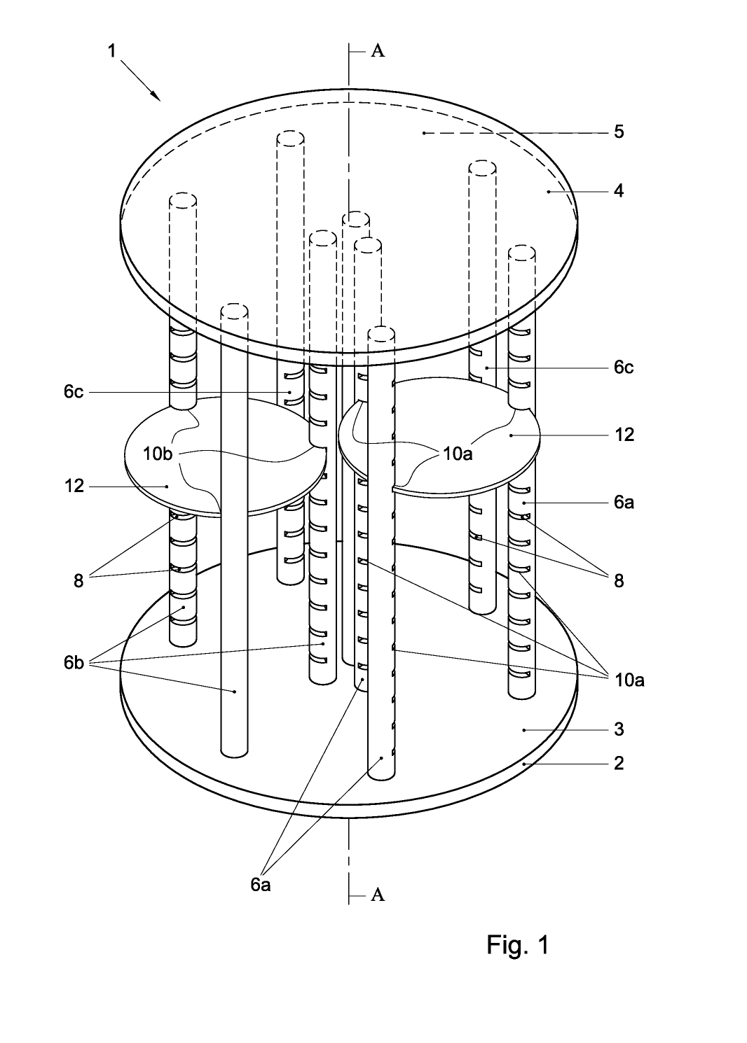

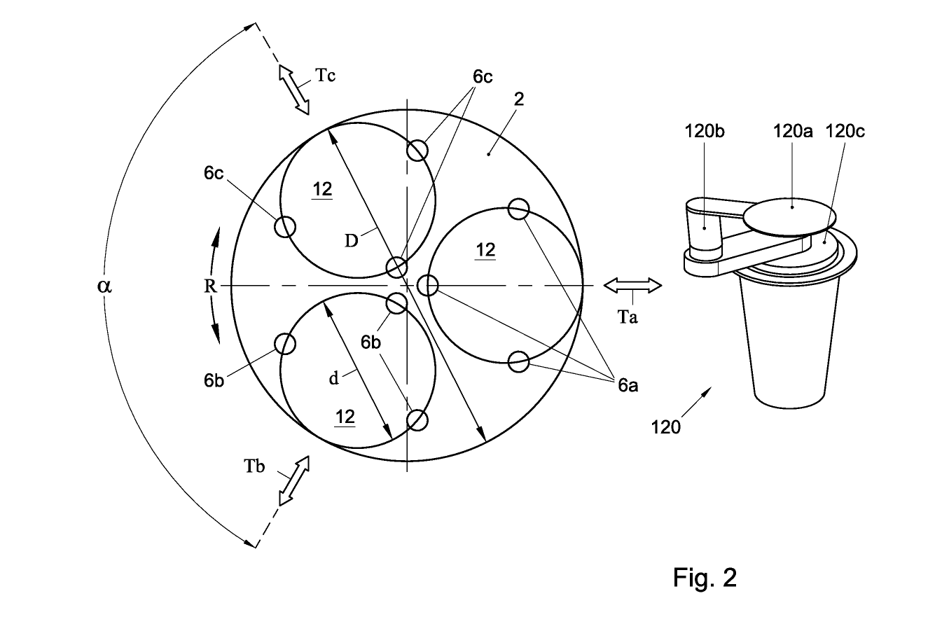

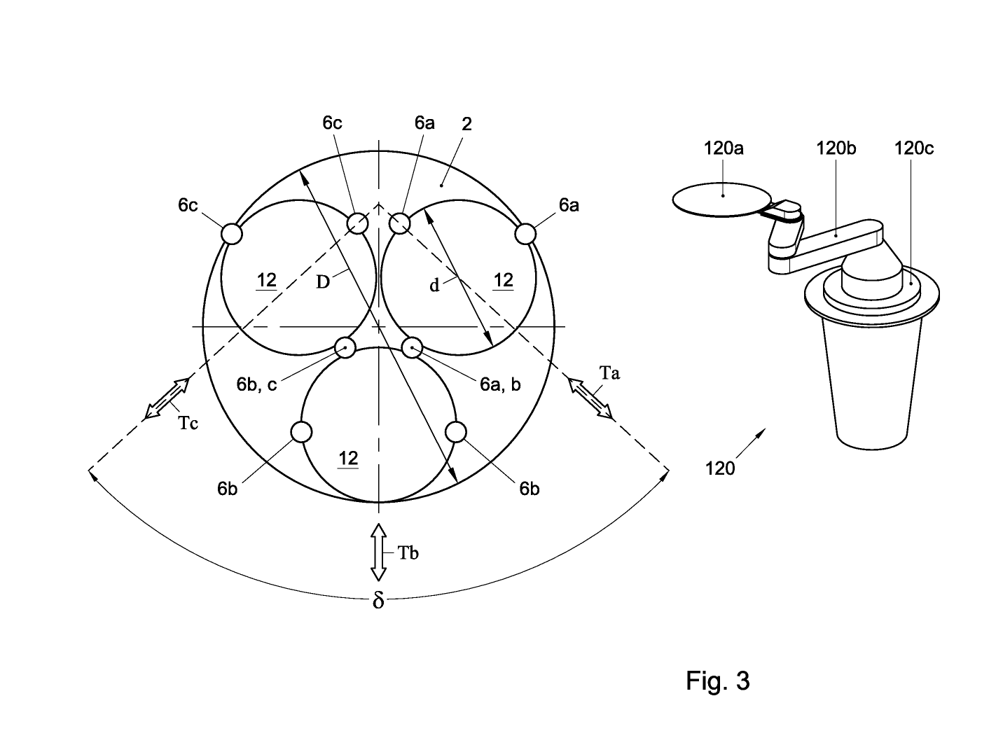

To elucidate the general construction of a vertical wafer boat according to the present invention, reference is made to FIGS. 1-4. FIGS. 1 and 2 (left) show, respectively, a schematic perspective view and a schematic cross-sectional top view of a first exemplary embodiment of a wafer boat 1 according to the present invention. FIGS. 3 (left) and 4 show schematic cross-sectional top views of, respectively, a second and third exemplary embodiment of a wafer boat 1 according to the present invention, having a construction comparable to the wafer boat 1 shown in FIGS. 1 and 2 (left), but with a different number and/or arrangement of rod-shaped support members 6.

Referring now to FIGS. 1-4, and in particular FIGS. 1 and 2. A wafer boat 1 according to the present invention may comprise a first end member 2 at a first, lower extremity of the wafer boat 1, and a second end member 4 at a second, upper and opposite extremity of the wafer boat. The first and second end members 2, 4 may be circular and generally plate-shaped, as shown in FIG. 1, but need not be. In typical embodiments both the first and the second end member 2, 4 may at least include a preferably horizontally oriented and planar main surface 3, 5, which main surfaces may be arranged in a vertically spaced apart, facing relationship wherein the two planar surfaces 3, 5 extend in parallel.

The wafer boat 1 may further comprise at least one support member. In one embodiment, such as the embodiment of FIGS. 1 and 2 (left), the at least one support member may comprise a plurality of rod-shaped support members, or rods 6. The rods 6 may preferably be straight, and extend substantially vertically and mutually parallel between the first and second end members 2, 4. The end members 2, 4 may fix the relative positions of the ends of the rods 6, and thus provide structural strength to the wafer boat 1. Each rod 6 may define a plurality of preferably equidistantly, vertically spaced apart wafer engagement provisions 8, for instance in the form of (support) protrusions or recesses. As one skilled in the art will appreciate, it may generally be possible to integrate the functionality of some or all rods 6 into a single, integrally formed support member. The open structure provided by the separate rods 6, however, may be preferred as it facilitates the flow of process gases through the wafer boat 1, and additionally minimizes material usage and thus lowers the weight and manufacturing costs of the boat. It is also contemplated that some embodiments, in particular rod-less embodiments, may not include any end members 2, 4. In embodiments of the wafer boat 1 that do include rod-shaped support members 6, the rods need not necessarily be straight; neither do they have to extend in parallel.

In an embodiment, at least one of the first end member 2, the second end member 4 and the at least one support member, e.g. the rods 6, may be manufactured from quartz, fused silica or silicon carbide.

As regards the arrangement of the rods 6, the following is noted. The rods 6 may be grouped into a plurality of sets each comprising at least two, and preferably at least three rods 6. The number of rods 6 need not be the same for different sets, and different sets may have one or more rods in common, as will be clarified below. Rods 6 belonging to the same set may be arranged such that their wafer engagement provisions 8 at a same or approximately the same vertical coordinate together define a wafer holding provision 10, configured to independently hold a wafer 12 in a substantially horizontal orientation at said vertical coordinate. To this end, the wafer engagement provisions 8 of a certain wafer holding provision 10 may lie on the contour of a circumferential edge of a wafer 12 to be held. For circular wafers 12, the wafer engagement provisions 8 of a certain wafer holding provision 10 may preferably be arranged to subtend an angle of approximately 180° with respect to the geometric center of the circular contour on which they are arranged, so as to stably support a respective wafer while enabling its insertion and removal. The respective pluralities of vertically spaced apart wafer engagement provisions 8 defined by each of the respective rods 6 belonging to certain set may thus define a set of vertically spaced apart wafer holding provisions 10 for accommodating a stack of wafers. Accordingly, each set of rods 6 may provide for a set of wafer holding provisions 10, which may be associated with a stack of wafers to be accommodated.

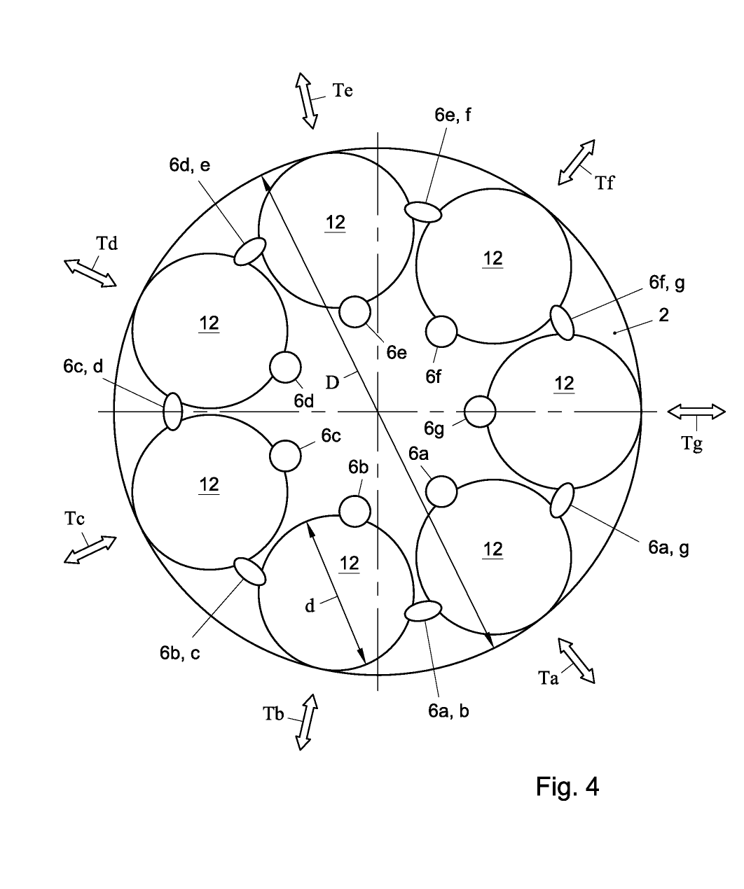

The wafer boat 1 of the embodiment of FIGS. 1 and 2 (left) includes three sets of rods 6a, 6b, 6c, each set comprising three rods. Any two of the three sets of rods 6a, 6b, 6c are disjoint (their respective intersections are empty), meaning that any two of the three sets have no rod 6 in common.—For clarity, rods 6 belonging to the same set are indicated with a same alphabetic suffix. The three rods labelled 6a thus belong to a same set. The three rods 6b likewise belong to a same set that is different from that to which the rods labelled 6a belong. The reference numbers 6a, 6b, 6c, etc. may be used to refer to both an individual rod of a certain set, and to a respective set of rods as a whole; the meaning of the reference will be clear from the context.—The wafer boat 1 of FIG. 3 also includes three sets of rods 6a, 6b, 6c: two sets of three rods 6a, 6c, and one set of four rods 6b. Each of the two three-rod sets 6a, 6c has one rod, respectively 6a,b and 6b,c, in common with the set of four rods 6b. The shared rods 6a,b and 6b,c are not the same. The wafer boat of FIG. 4 includes seven sets of rods 6a-g, each set comprising three rods. Any two tangentially adjacent sets 6a-g of rods have one rod in common, e.g. 6a,b, 6b,c, 6c,d, etc.

It will be clear from an inspection of the schematic cross-sectional top views of FIGS. 2 (left), 3 and 4 that the rods 6 of the depicted embodiments all extend vertically, while rods of a same set 6a, 6b, etc.—seen in a top view—are each time arranged on a circle. Accordingly, the exemplary wafer boats 1 are all configured to accommodate straight, parallel stacks of circular wafers 12. Other embodiments of the wafer boat 1, however, may be configured to accommodate juxtaposed stacks that are not straight, but for example staggered, and/or to accommodate stacks of wafers 12 having a different circumferential shape, e.g. rectangular.

In general, each of the wafers 12 to be held in the boat 1 may be characterized by a main surface dimension d. For a circular wafer d may correspond its diameter, while for a rectangular wafer d may correspond to its edge length. The wafer boat 1 according to the present invention may be configured to accommodate stacks of relatively small-sized wafers 12 having a characteristic main surface dimension d≦200 mm, and preferably d≦150 mm. The wafer boat 1 as a whole, and hence the arrangement of stacks, in turn, may preferably fit inside a cylindrical envelope, corresponding to a cylindrical wafer boat reception space of a reactor tube of a vertical furnace, having a diameter D smaller than approximately 350 mm for reactors with a wafer target size of 300 mm, and smaller than approximately 500 mm for reactors with a wafer target size of 450 mm. FIGS. 2 and 3 illustrate, by way of example, how three 150 mm wafers 12 may be arranged in juxtaposition within a circular footprint of a cylindrical wafer boat reception space having a diameter D of 340 mm. It may be observed that the arrangement of FIGS. 2 and 3 is also applicable to three 200 mm wafers 12 to be arranged within a circular footprint with a diameter D of about 465 mm. FIG. 4 illustrates how seven 100 mm wafers 12 may be juxtaposed within a circular envelope with a diameter D of about 340 mm.

Although the wafer boat embodiments of FIGS. 2 and 3 are both configured to accommodate three straight parallel stacks of wafers 12, their respective rod arrangements differ. The difference is of consequence to the directions along which wafers 12 may be inserted into and removed from the wafer holding positions 10 associated with the respective stacks. In particular in a wafer boat embodiment configured to accommodate straight and parallel stacks of wafers 12, each set 10a, 10b, etc. of wafer holding positions may be associated with a wafer transfer direction Ta, Tb, etc., i.e. the direction along which wafers 12 are insertable into and removable from the wafer holding provisions of the respective set 10a, 10b, etc. The wafer transfer direction Ta, Tb, etc. may typically be oriented substantially horizontally, and thus be represented by a bidirectional, substantially horizontally extending arrow.

In the wafer boat embodiment of FIG. 2, the wafer transfer directions Ta, Tb, etc. of any two tangentially adjacent sets 10a, 10b, etc. of wafer holding positions include an angle of 120°. Consequently, if the loading and unloading of wafers 12 into and from the wafer boat 1 is handled by a common three-link wafer handling robot 120 (as shown in FIG. 2 (right)) whose backbone 120c is fixed in space, it may be necessary to rotate the wafer boat 1 around its central axis A in the direction R to successively make each set of wafer holding positions 10a, 10b, etc. face the robot 120.

Such need for a boat rotation mechanism may, however, be overcome by using a different rod arrangement. In the embodiment of FIG. 3, the rods 6 are arranged such that the wafer transfer directions Ta-c of all three sets 10a-c of wafer holding positions are included in an angle less than 120°. As a result, wafers 12 may be inserted into and removed from all three sets of wafer holding positions 10a-c using a non-rotatably mounted wafer boat 1 in combination with a wafer handling robot 120 that includes an articulated arm 120b with, preferably, at least three links and an end-effector 120a that is movably, in particular rotatably, connected to an extremity of the three-link arm 120b.

In general, in a preferred embodiment the plurality of sets of wafer holding provisions 10a, 10b, etc. associated with respective stacks of wafers 12 may include at least two sets whose respective wafer transfer directions Ta, Tb, etc. include an angle <90°. In another embodiment, the plurality of sets of wafer holding provisions 10a, 10b, etc. may include at least three sets whose three respective wafer transfer directions Ta, Tb, etc. are included in an angular range <120°.

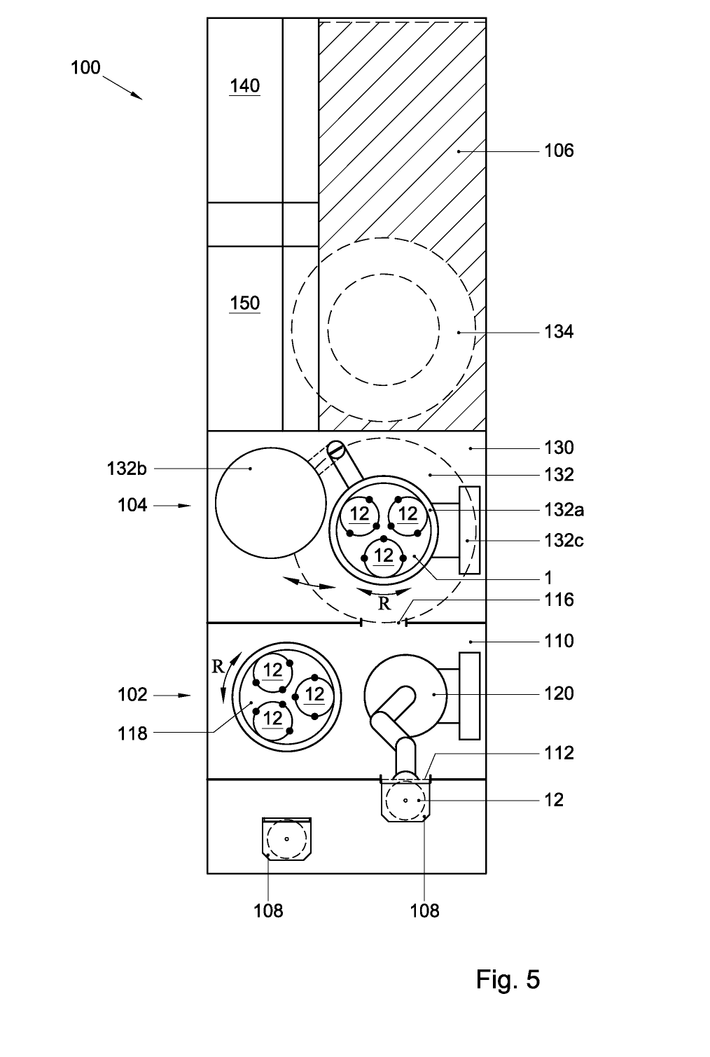

FIG. 5 shows a schematic plan view of an exemplary semiconductor processing apparatus 100, in particular a vertical furnace, fitted with the first exemplary embodiment of the wafer boat 1 shown in FIGS. 1 and 2. The semiconductor processing apparatus 100 may include a wafer transfer module 102 (sometimes referred to as an equipment front end module (EFEM)), and a reactor module 104 that forms the parent tool to which the wafer transfer module 102 has been added.

The wafer transfer module 102 may include at least one wafer cassette input/output (I/O-) port 112 to which a wafer cassette or pod 108 may be detachably docked. The docking of a pod 108 may allow a moving door of the respective I/O-port 112 to be opened so as to bring the micro-climate inside the wafer cassette 108 in fluid communication with the atmosphere in a wafer transfer chamber 110 of the wafer transfer module 102, and to enable access to the wafers 12 inside the wafer cassette 108.

The wafer transfer chamber 110 of the wafer transfer module 102 may accommodate a wafer handling robot 120 and a wafer depository 118. The wafer handling robot 120 may be of a conventional design (cf. FIGS. 2 (right) and 3 (right)), and for example be of the SCARA (Selectively Compliant Articulated Robot Arm) or frog-leg type. In general, the wafer handling robot 120 may include an end-effector 120a, e.g. a mechanical or negative pressure type end-effector for one or more wafers 12, that is provided at an extremity of an articulated arm 120b comprising a number of links that are interconnected via optionally parallel, drivable axes. The arm 120b may itself be rotatably mounted on a backbone or base 120c that includes a lift mechanism to enable the arm 120b to both rotate around and travel along the vertical axis. Accordingly, the wafer handling robot 120 may have a 270°, and preferably 360° motion range (around the vertical axis) across which it can radially extend and retract at varying heights to pick up and deliver wafers 12, in particular from and to a docked pod 108, the wafer depository 118, and a wafer boat 1 of the reactor 132 as described above. The wafer depository 118 may be a passive rack, identical or similar to a wafer boat 1 according to the present invention and configured to temporarily store a plurality of wafers 12. In particular in case the wafer depository 118 defines multiple sets of wafer holding provisions, it may be rotatably mounted around a vertical axis such that wafers 12 may be conveniently inserted into the wafer holding provisions of the various sets by the wafer handling robot 120.

At the back of the wafer transfer module 102, the processing apparatus 100 may include the reactor module 104. In the exemplary processing apparatus 100 of FIG. 5, a first section of the reactor module 104, located adjacent the back wall of the wafer transfer module 102, includes a reactor cabinet 130 that accommodates a single vertical thermal batch furnace 132 for simultaneously processing a plurality of wafers. The vertical furnace 132 may define a heatable bell shaped reaction tube 132a, a lower end of which may be open so as to allow a wafer boat 1 to be introduced therein from below. To lift the wafer boat 1 into the reaction tube 132a before processing, and to lower the wafer boat from the reaction tube after processing, the reactor 132 may include a lift mechanism 132c. In some embodiments, such as the one depicted in FIG. 5, the lift mechanism may include a rotation mechanism that enables the wafer boat 1 to be rotated around its central vertical axis. A door plate, integrated with a pedestal that supports the wafer boat 1, may seal the reaction tube 132a during processing. In addition, a horizontally moveable, motor driven shutter plate 132b may be provided to close the opening of the reaction tube 132a during the time the wafer boat 1 is removed from the reaction tube and to limit the heat radiation emanating from the reaction tube. Further to the back, the reactor module 104 may additionally define a power cabinet 140 and a gas cabinet 150. The power cabinet 140 may accommodate all primary electrical components of the processing apparatus 100, and distribute electrical facilities to the gas cabinet 150, the reactor 142 and the wafer transfer module 102, in particular to the wafer handling robot 122 thereof. The gas cabinet 150 may accommodate all process gas facilities, including for example pressure gauges, flow controllers, valves, a process gas controller, and peripheral equipment.

In use, a pod 108 may be docked to the I/O-port 112 of the wafer transfer module 102. The wafer handling robot 120, which in the depicted embodiment includes a three-link articulated arm (cf. FIG. 2 (right)) may pick up the wafers 12 from the pod 108 and place them in the wafer boat 1 of the reactor 132 disposed in the reactor cabinet 130. In doing so, it may first fill all wafer holding provisions 10a of a first set of wafer holding provisions. Once the respective set is filled, the wafer boat 1 may be rotated around its central vertical axis A by means of the wafer boat lift and rotation mechanism 132c, so as to turn a second empty set of wafer holding provisions 10b towards the robot 120. Then this second set of wafer holding provisions, e.g. 10b, may be filled. The process may continue until the wafer boat 1 is loaded with a plurality juxtaposed wafer stacks. Once the wafer boat 1 is fully loaded, the shutter 132b may move into a position in which the reaction tube 142a is open, and the lift and rotation mechanism 132c may lift the wafer boat 1 into the reaction tube 142a, in which the wafers may be processed. When the processing of the wafers 12 is completed, the above actions may be executed in reverse order to again collect the wafers in the pod 108.

As regards the terminology used in this text, the following is noted.

The term ‘substantially horizontal’ and adverbial derivates thereof may be interpreted to refer to a direction or orientation that includes an angle in the range of 0±15° with the horizontal. The term ‘substantially vertical’ and adverbial derivatives thereof may be interpreted to refer to a direction or orientation that includes an angle in the range of 90±15° with the horizontal. The terms ‘horizontally spaced apart’ and ‘vertically spaced apart’ may be interpreted within the framework of a right-handed Cartesian coordinate system, wherein the x- and y-directions define the horizontal plane, and the z-axis defines the vertical. In relation to the coordinate system, the term ‘horizontally spaced apart’ may be construed to mean ‘having different horizontal or x- and y-coordinates’. Similarly, the term ‘vertically spaced apart may be construed to mean ‘having different vertical or z-coordinates’; accordingly, two vertically spaced apart objects may but need not be located straight above one another. The term ‘juxtaposed’ may generally be construed to mean ‘beside one another’, or ‘horizontally spaced apart’. Furthermore, a ‘stack of wafers’ may be construed to refer to a series of least two wafers arranged in a mutually vertically spaced apart relationship, wherein any two consecutively arranged wafers exhibit an at least partial horizontal overlap. The term ‘juxtaposed stacks of wafers’ may be construed to refer to at least two stacks of wafers, wherein the wafers of different stacks, at least insofar as they are positioned at a same or approximately the same vertical coordinate, are horizontally spaced apart. The notion of ‘juxtaposed stacks of wafers’ may thus include the condition that none of the wafers of a first of said stacks extends into between two consecutively stacked wafers in a second of said stacks.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims. Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments.

### LIST OF ELEMENTS

1 wafer boat
2 first end member
3 planar main surface of first end member
4 second end member
5 planar main surface of second end member
6 rod-shaped support member
6a, 6b support member belonging to set a, respectively, set b
6a,b support member belonging to sets a and b
8 wafer engagement provision (recess)
10 wafer holding provision
10a, 10b wafer holding provision belonging to set a, respectively, set b
12 wafer
100 semiconductor processing apparatus
102 wafer transfer module
104 reactor module
106 maintenance space
108 pod
110 substrate transfer chamber
112 substrate cassette I/O-port
116 wafer transfer passage
118 wafer depository
120 substrate handling robot
120a end-effector
120b articulated arm
120c backbone of substrate handling robot
130 reactor cabinet
132 reactor
132a reactor tube
132b shutter plate
132c wafer boat lift and rotation mechanism
134 reactor position when moved into maintenance space
140 power cabinet
150 gas cabinet
A central axis of wafer boat
D diameter envelope of wafer boat
d main surface dimension (e.g. diameter or edge length)
Ta, Tb wafer transfer direction of wafer holding provisions set a, respectively, set b
R wafer boat rotation direction
, angle between different wafer transfer directions

1. A wafer boat for holding a plurality of semiconductor wafers in a spaced apart relationship during processing, comprising at least one support member defining a plurality of sets of at least two vertically spaced apart wafer holding provisions, each of which wafer holding provisions is configured to independently hold a wafer in a substantially horizontal orientation, and wherein said sets are arranged such that the wafer boat is configured to accommodate a plurality of juxtaposed stacks of substantially horizontally oriented, vertically spaced apart wafers.

2. The wafer boat according to claim 1, wherein said plurality of sets of wafer holding provisions includes at least three such sets, such that the wafer boat is configured to accommodate at least three juxtaposed stacks of wafers.

3. The wafer boat according to claim 1, further comprising a first end member at a lower extremity of the wafer boat and a second end member at an upper extremity of the wafer boat,
wherein said at least one support member includes a plurality of rod-shaped support members, each interconnecting said end members and defining a plurality of vertically spaced apart wafer engagement provisions,
wherein each set of wafer holding provisions is defined by a set of at least two rod-shaped support members, and wherein each individual holding provision of a certain set of wafer holding provisions is defined by at least two wafer engagement provisions defined by the rod-shaped support members defining the respective set of wafer holding provisions.

4. The wafer boat according to claim 3, wherein said wafer engagement provisions are formed by recesses in said rod-shaped support members.

5. The wafer boat according to claim 3, wherein the rod-shaped support members are substantially straight and extend in parallel between the end members, such that the wafer boat is configured to accommodate a plurality of straight, parallel stacks.

6. The wafer boat according to claim 3, wherein each set of wafer holding provisions is defined by a set of at least three rod-shaped support members.

7. The wafer boat according to claim 3, wherein at least two sets of rod-shaped support members have at least one rod-shaped support member in common.

8. The wafer boat according to claim 3, wherein at least two sets of rod-shaped support members have no rod-shaped support member in common.

9. The wafer boat according to claim 1, wherein each set of wafer holding provisions is associated with a wafer transfer direction along which wafers are insertable into and removable from the wafer holding provisions of the respective set, and
wherein said plurality of sets of wafer holding provisions includes at least two sets whose respective wafer transfer directions include an angle <90°.

10. The wafer boat according to claim 9, wherein said plurality of sets of wafer holding provisions includes at least three sets of which any two respective wafer transfer directions include an angle <120°.

11. The wafer boat according to claim 1, wherein each of said wafer holding provisions is configured to hold a semiconductor wafer having a characteristic main surface dimension d≦200 mm, and preferably d≦150 mm.

12. A semiconductor processing apparatus, in particular a vertical furnace, comprising a wafer boat according to claim 1.

13. The semiconductor processing apparatus according to claim 12, comprising:
a reactor tube;
a pedestal, supporting the wafer boat, and configured to be at least partly insertable into the reactor tube; and
a wafer handling robot, including a multi-link articulated arm, configured to load and unload wafers into and from the wafer holding provisions of each of the sets of wafer holding provisions of the wafer boat.

14. The semiconductor processing apparatus according to claim 13, wherein the articulated arm of wafer handling robot includes at least three links.

15. The semiconductor processing apparatus according to claim 13, wherein the wafer boat is rotatably arranged around its central axis.
